(19) United States
(12) Patent Application Publication
(10) Pub. No.: US 2011/0033284 A1
(43) Pub. Date: Feb. 10, 2011

(54) STRUCTURALLY DIVERSE THERMAL BARRIER COATINGS

(75) Inventors: Brian S. Tryon, Glastonbury, CT (US); Kevin W. Schlichting, South Glastonbury, CT (US); Melvin Freling, West Hartford, CT (US); David A. Litton, West Hartford, CT (US)

Correspondence Address: BACHMAN & LAPOINTE, P.C. (P&W), 900 CHAPEL STREET, SUITE 1201, NEW HAVEN, CT, 06510-2802, US

(73) Assignee: UNITED TECHNOLOGIES CORPORATION, Hartford, CT (US)

(21) Appl. No.: 12/534,945

(22) Filed: Aug. 4, 2009

(51) Int. Cl. F01D 25/08; B32B 9/04; B05D 1/36; C23C 16/44

(52) U.S. Cl. 415/177; 428/411.1; 428/701; 427/419.2; 427/255.7; 427/454

(57) ABSTRACT

A coated article includes an article having at least one surface and a thermal barrier coating system disposed upon the at least one surface. The thermal barrier coating system has at least two layers, with each layer having a different microstructure. The microstructure of each layer may be any one of the following: columnar, amorphous, randomized, and splat-like. The thermal barrier coating system typically exhibits a thermal conductivity of no more than 16 BTU in/hr ft² F.

### BACKGROUND

The invention relates to thermal barrier coatings and, more particularly, relates to reduced conductivity thermal barrier coating systems having at least two layers, each layer exhibiting a different microstructure.

Thermal barrier coatings (hereinafter “TBCs”) are employed in turbine engines in an effort to shield and protect the structural metallic components from the high temperature conditions present in a combustion environment. These ceramic coatings effectively lower the substrate metal surface temperature and slow the kinetics of oxidation which degrades the metallic substrate. Reduced conductivity TBCs have provided an even greater benefit to turbine engines than conventional TBCs by allowing higher turbine engine operation temperatures or even further reduced metal substrate temperatures. The microstructure of a TBC is dictated by processing. The microstructure also contributes to the physical properties of the coated article, in particular, the thermal conductivity. When creating thermal barrier coatings, it is desirable to reduce the thermal conductivity of the TBCs as much as possible.

### SUMMARY

In one aspect of the present disclosure, a coated article broadly comprises an article having at least one surface; and a thermal barrier coating system disposed upon at least one surface and comprising at least two layers, each layer having a different microstructure, wherein the thermal barrier coating system exhibits a thermal conductivity of no more than 16 BTU in/hr ft² F.

In another aspect of the present disclosure, a coated article broadly comprises a turbine engine component having at least one surface; and a thermal barrier coating system disposed upon the at least one surface. The thermal barrier coating system comprises at least two layers, with each layer having a different microstructure. In a preferred embodiment, the at least two layers broadly comprises: a first layer having a first microstructure; a second layer having a second microstructure; and an interlayer having a third microstructure and formed between the first and second layers, wherein the first and second microstructures comprise a microstructure selected from the group consisting of columnar, amorphous, randomized, and splat-like, wherein the third microstructure comprises a combination of the first and second microstructures, and wherein the thermal barrier coating system exhibits a thermal conductivity of no more than 16 BTU in/hr ft² F.

In yet another aspect of the present disclosure, a process for coating an article broadly comprises applying a first layer of a thermal barrier coating system having a first microstructure on at least one surface of an article; applying upon the first layer a second layer of the thermal barrier coating system having a second microstructure that is different from the first microstructure; and forming between the first and second layers an interlayer having a third microstructure comprising a combination of the first and second microstructures.

The details of one or more embodiments of the invention are set forth in the accompanying drawings and the description below. Other features, objects, and advantages of the invention will be apparent from the description and drawings, and from the claims.

### BRIEF DESCRIPTION OF THE DRAWINGS

FIG. 1 is a flowchart of an exemplary process for coating an article according to the present disclosure;

FIG. 2 is a representation of an exemplary embodiment of a bi-layered reduced conductivity TBC exhibiting different microstructures and/or morphologies; and

FIG. 3 is a representation of another exemplary embodiment of a multi-layered reduced conductivity TBC exhibiting different microstructures and/or morphologies.

Like reference numbers and designations in the various drawings indicate like elements.

### DETAILED DESCRIPTION

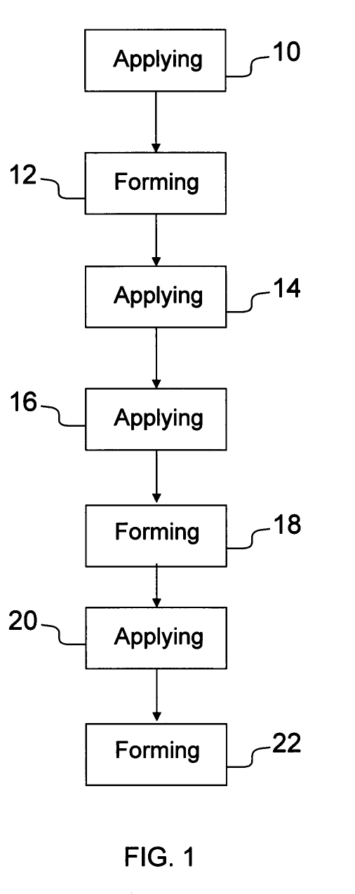

Referring to FIG. 1, an exemplary process for coating an article according to the present disclosure is illustrated. The article to be coated may comprise a turbine engine component to which a reduced thermal conductivity thermal barrier coating system may be applied. The exemplary thermal barrier coating system exhibits a thermal conductivity of no more than about 16 BTU in/hr ft² F. The thermal barrier coating system as described herein increases the surface temperature capability of the coated article. In a first embodiment of the present invention, the thermal conductivity of the thermal barrier coating system may be in the range of 2.0 to 16 BTU in/hr ft² F. In a second embodiment of the present invention, the thermal conductivity of the thermal barrier coating system may be in the range of from 4.0 to 14 BTU in/hr ft² F. In yet another embodiment of the present invention, the thermal conductivity of the thermal barrier coating system may be in the range of from 4.0 to 10 BTU in/hr ft² F.

If desired, an optional bond coat layer may be applied on at least one surface of the article at step 10 prior to the application of the thermal barrier coating system. The bond coat layer may be applied using any suitable technique known in the art. If desired, a thermally grown oxide layer (“TGO”) may be formed upon the bond coat layer at step 12 using any suitable technique known in the art. Alternatively, the thermal barrier coating system may be directly applied to, or deposited on, the at least one surface of the article.

A first layer of a thermal barrier coating may be applied upon the at least one surface of the article, or the bond coat layer if present or the thermally grown oxide layer if present, at step 14. A second layer of the thermal barrier coating may be deposited on the first layer at step 16. During the second layer deposition process, an interlayer typically forms between the first and second layers of the thermal barrier coating at step 18. One or more additional layers may be applied upon the second layer at step 20 such that additional interlayer(s) form between each layer subsequently applied at step 22. Each layer of the thermal barrier coating system preferably has a different microstructure. For example, the first layer has a first microstructure, the second layer has a second microstructure, and the interlayer has a microstructure exhibiting a combination of the first and second microstructures.

The application of the bond coat and the first, second and any subsequent layers of the thermal barrier coating system may be achieved using either a vapor deposition process (e.g., physical vapor deposition) or a thermal spray process (e.g., plasma spraying) as known to one of ordinary skill in the art. Whether using a vapor deposition process or a thermal spray process, each layer of the thermal barrier coating system, and the bond coat layer, is applied so that each layer exhibits a different microstructure. The microstructures contemplated herein include, but are not limited to, columnar, amorphous, randomized, and splat-like microstructures. Whether using a vapor deposition process or a thermal spray process, each layer of the thermal barrier coating may be applied using a vacuum-plasma spraying torch apparatus known as the O3CP, commercially available from Sulzer Metco Ltd., of Westbury, N.Y. The O3CP vacuum-plasma spraying apparatus allows a user to apply a first coating exhibiting a microstructure such as a columnar microstructure, and then adjust the operating parameters of the spraying apparatus to apply a subsequent coating exhibiting a different microstructure. Prior processes required one of ordinary skill in the art to utilize two entirely different spraying apparatus to apply coatings having different microstructures as disclosed herein. In using the O3CP vacuum-plasma spraying apparatus to perform the exemplary process described herein, one recognizes benefits such as reduced time and costs, increased efficiency, and minimized likelihood of contaminating the thermal barrier coating system being applied.

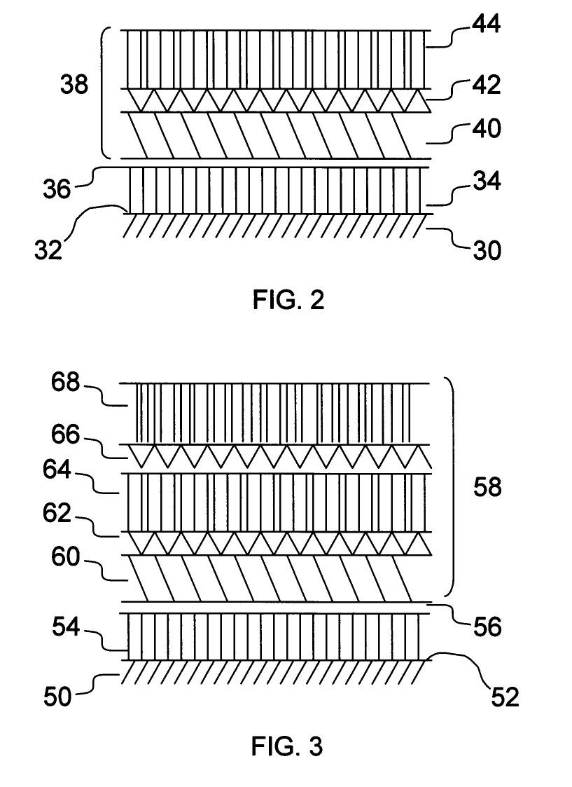

Referring now to FIGS. 2 and 3, these drawings illustrate representations of exemplary coated articles 30, 50 produced according to the exemplary processes described herein. The exemplary thermal barrier coating system having layers exhibiting different microstructures and possessing a reduced thermal conductivity over thermal barrier coating systems having homogeneous microstructures. Each article 30, 50 may comprise a surface 32, 52 having a bond coat layer 34, 54 disposed thereupon. The bond coat may be either a MCrAlY coating where M is nickel and/or cobalt, an aluminide coating, a platinum aluminide coating, a ceramic based bond coat, or a silica based bond coat. The bond coat layer 34, 54 aids the growth of the TGO 36, 56, which is typically aluminum oxide (Al₂O₃). Specifically, prior to or during application of the exemplary thermal barrier coating system described herein on the bond coat layer, the exposed surface of the bond coat layer 34, 54 can be oxidized to form the TGO 36, 56.

Referring now to FIG. 2, an exemplary thermal barrier coating system 38 may comprise a bi-layer thermal barrier coating. The thermal barrier coating system 38 may comprise a first layer 40 having a first microstructure disposed upon the surface 32 of the article 30, or the bond coat layer 34 or the TGO 36 when present. The coating system 38 may also comprise a second layer 44 having a second microstructure, and an interlayer 42 formed between the first layer 40 and the second layer 44. The interlayer 42 may be formed gradually or abruptly depending upon the transition between the applications of the first layer 40 and the second layer 44. As a result, the interlayer 42 may have a third microstructure possessing a combination of the first and second microstructures, that is, structural elements and variants of the first and second microstructures.

Referring now to FIG. 3, another exemplary thermal barrier coating system 58 may comprise a multi-layered system. Thermal barrier coating system 58 may also comprise the first layer 60, the interlayer 62 and the second layer 64 as described above for thermal barrier coating system 38. In addition, the coating system 58 may comprise a third layer 68 having a fourth microstructure, and another interlayer 66 formed between the second layer 64 and third layer 68. The interlayer 66 may comprise a fifth microstructure. As described above, interlayer 66 may be formed in the same manner such that the fifth microstructure contains structural elements and variants of both the third and fourth microstructures.

Each layer of the thermal barrier coating system may include a ceramic base material and at least one dopant oxide of a metal present in an amount of about 1 wt % to about 99 wt %, and from about 5 wt % to about 99 wt %, and from about 30 wt % to about 70 wt %, of the total weight of the layer. Suitable ceramic base materials may include any one of the following: a zirconate, a hafnate or a titanate. Suitable dopant oxides of a metal may include oxides of any one of the following metals: lanthanum, cerium, praseodymium, neodymium, promethium, samarium, europium, gadolinium, terbium, dysprosium, holmium, erbium, thulium, ytterbium, lutelium, indium, scandium, and yttrium. For example, a representative thermal barrier coating system may comprise yttria stabilized zirconia having from about 1.0 wt % to about 25 wt % yttria of the total weight of the layer and a balance of zirconia, or gadolinia stabilized zirconia having from about 5.0 wt % to about 99 wt % gadolinia, from about 30 wt % to about 70 wt % gadolinia, of the total weight of the layer and a balance of zirconia or both yttria stabilized zirconia and gadolinia stabilized zirconia.

One or more embodiments of the present invention have been described. Nevertheless, it will be understood that various modifications may be made without departing from the spirit and scope of the invention. Accordingly, other embodiments are within the scope of the following claims.

What is claimed is:

1. A coated article, comprising:
an article having at least one surface; and
a thermal barrier coating system disposed upon said at least one surface;
said thermal barrier coating system comprising at least two layers;
each of said layers having a different microstructure than the other of said layers,
wherein said thermal barrier coating system exhibits a thermal conductivity of no more than 16 BTU in/hr ft² F.

2. The coated article of claim 1, wherein said thermal barrier coating system comprises:
a first layer having a first microstructure;
a second layer having a second microstructure; and
a first interlayer having a third microstructure formed between said first and second layers.

3. The coated article of claim 2, wherein said first and second microstructures comprise a microstructure selected from the group consisting of columnar, amorphous, randomized, and splat-like.

4. The coated article of claim 2, wherein said third microstructure comprises a combination of said first and second microstructures.

5. The coated article of claim 2, wherein said thermal barrier coating system further comprises:
a third layer having a fourth microstructure; and
a second interlayer having a fifth microstructure formed between said second and third layers.

6. The coated article of claim 5, wherein said fourth microstructure has a microstructure selected from the group consisting of columnar, amorphous, randomized, and splat-like.

7. The coated article of claim 5, wherein said fifth microstructure comprises a combination of said second and fourth microstructures.

8. The coated article of claim 1, wherein at least one layer of said thermal barrier coating system includes:
a ceramic base material selected from the group consisting of a zirconate, a hafnate and a titanate; and
at least one dopant oxide of a metal present in an amount from about 1 wt % to about 99 wt % of the total weight of said layer, said metal comprising at least one metal selected from the group consisting of lanthanum, cerium, praseodymium, neodymium, promethium, samarium, europium, gadolinium, terbium, dysprosium, holmium, erbium, thulium, ytterbium, lutelium, indium, scandium, and yttrium.

9. The coated article of claim 8, wherein said at least one oxide of a metal is present in an amount from about 30 wt % to about 70 wt. % of the total weight of said layer.

10. The coated article of claim 1, wherein said thermal conductivity is in the range of from 2.0 to 16 BTU in/hr ft² F.

11. The coated article of claim 1, wherein said thermal conductivity is in the range of from 4.0 to 14 BTU in/hr ft² F.

12. The coated article of claim 1, wherein said thermal conductivity is in the range of from 4.0 to 10 BTU in/hr ft² F.

13. A coated article, comprising:
a turbine engine component having at least one surface;
a thermal barrier coating system disposed upon said at least one surface; and
said thermal barrier coating system comprising a first layer having a first microstructure, a second layer having a second microstructure, and an interlayer having a third microstructure formed between said first and second layers,
wherein said first and second microstructures comprise any one of the following microstructures: columnar, amorphous, randomized, and splat-like,
wherein said third microstructure comprises a combination of said first and second microstructures, and
wherein said thermal barrier coating system exhibits a thermal conductivity of no more than 16 BTU in/hr ft² F.

14. The coated article of claim 13, wherein each layer of said thermal barrier coating system comprises yttria stabilized zirconia having from about 1.0 wt % to about 25 wt % yttria of the total weight of said layer and a balance of zirconia or gadolinia stabilized zirconia having from about 5.0 wt % to about 99 wt % gadolinia of the total weight of said layer and a balance of zirconia or both said yttria stabilized zirconia and said gadolinia stabilized zirconia.

15. The coated article of claim 14, wherein said gadolinia stabilized zirconia includes from about 30 wt % to about 70 wt % gadolinia of the total weight of said layer and a balance of zirconia.

16. The coated article of claim 13, further comprising a bond coat layer disposed between said at least one surface and said thermal barrier coating system.

17. The coated article of claim 16, further comprising a thermally grown oxide layer disposed between said bond coat layer and said thermal barrier coating system.

18. The coated article of claim 13, wherein said thermal barrier coating further comprises:
a third layer having a fourth microstructure; and
a second interlayer having a fifth microstructure formed between said second and third layers,
wherein said fourth microstructure comprises any one of the following microstructures: columnar, amorphous, randomized, and splat-like, and
wherein said fifth microstructure comprises a combination of said second and fourth microstructures.

19. The coated article of claim 13, wherein said thermal conductivity is in the range of from 2.0 to 16 BTU in/hr ft² F.

20. The coated article of claim 13, wherein said thermal conductivity is in the range of from 4.0 to 14 BTU in/hr ft² F.

21. The coated article of claim 13, wherein said thermal conductivity is in the range of from 4.0 to 10 BTU in/hr ft² F.

22. A process for coating an article, comprising:
applying a first layer of a thermal barrier coating system having a first microstructure on at least one surface of an article;
applying upon said first layer a second layer of said thermal barrier coating system having a second microstructure that is different from said first microstructure; and
forming between said first and second layers an interlayer having a third microstructure comprising a combination of said first and second microstructures.

23. The process of claim 22, wherein the step of applying said first layer comprises applying a first layer having a first microstructure comprising any one of the following: columnar, amorphous, randomized, and splat-like.

24. The process of claim 22, wherein the step of applying said second layer comprises applying a second layer having a second microstructure comprising any one of the following: columnar, amorphous, randomized, and splat-like.

25. The process of claim 22, further comprising the steps of:
applying a bond coat layer upon said at least one surface of said article prior to applying said first layer; and
forming a thermally grown oxide layer upon said bond coat layer prior to applying said first layer.

26. The process of claim 25, wherein said steps of applying said first layer, applying said second layer and applying said bond coat layer comprise using a vapor deposition process or a thermal spraying process.
